(19) United States
(12) Patent Application Publication
(10) Pub. No.: US 2014/0213044 A1
(43) Pub. Date: Jul. 31, 2014

(54) METHOD FOR PRODUCING PERIODIC CRYSTALLINE SILICON NANOSTRUCTURES

(71) Applicants: Christiane Becker, Berlin (DE); Tobias Sontheimer, Berlin (DE); Matthias Bockmeyer, Mainz (DE); Eveline Rudigier-Voigt, Mainz (DE); Bernd Rech, Berlin (DE)

(72) Inventors: Christiane Becker, Berlin (DE); Tobias Sontheimer, Berlin (DE); Matthias Bockmeyer, Mainz (DE); Eveline Rudigier-Voigt, Mainz (DE); Bernd Rech, Berlin (DE)

(73) Assignee: HELMHOLTZ-ZENTRUM BERLIN FUER MATERIALIEN UND ENERGIE GMBH, Berlin (DE)

(21) Appl. No.: 14/240,034

(22) PCT Filed: Aug. 22, 2012
(86) PCT No.: PCT/IB2012/001989

§ 371 Date: Feb. 21, 2014

(30) Foreign Application Priority Data
Aug. 25, 2011 (DE) 10 2011 111 629.3

(51) Int. Cl. H01L 21/02; H01L 29/04

(52) U.S. Cl. CPC H01L 21/02667; H01L 29/04
USPC 438/479; 438/486

(57) ABSTRACT

A method for producing periodic crystalline silicon nanostructures of large surface area by: generating a periodic structure having a lattice constant of between 100 nm and 2 μm on a substrate, the substrate used being a material which is stable at up to at least 570° C., and the structure being produced with periodically repeating shallow and steep areas/flanks, and, subsequently, depositing silicon by directed deposition onto the periodically structured substrate, with a thickness in the range from 0.2 to 3 times the lattice constant, or 40 nm to 6 μm, at a substrate temperature of up to 400° C., followed by thermally treating the deposited Si layer to effect solid-phase crystallization, at temperatures between 570° C. and 1400° C., over a few minutes up to several days, and optionally subsequently wet-chemically selective etching to remove resultant porous regions of the Si layer.

### CROSS-REFERENCE TO RELATED APPLICATIONS

This application is a U.S. National Phase Application under 35 U.S.C. § 371 of International Application No. PCT/IB2012/001989 filed on Aug. 22, 2012, and claims benefit to German Patent Application No. DE 10 2011 111 629.3 filed on Aug. 25, 2011. The International Application was published in German on Feb. 28, 2013, as WO 2013/027123 A1 under PCT Article 21(2).

### FIELD

The invention relates to a method for preparing crystalline silicon periodic nanostructures.

### BACKGROUND

Periodic nanostructures—particularly photonic crystals are able to guide, filter and reflect light selectively by wavelength in dimensions within the magnitude of the wavelength of the light. They therefore constitute the basis for photonic components in which the transfer of information by light functions.

However, the production of photonic crystals represents a challenge to scientists, since the refractive index for such materials must undergo spatially periodic variation on the scale of the wavelength of light, that is to say in the in the sub-micrometre range. In this context, a large refractive index contrast, such as the difference between silicon or III-V semiconductors and air, is of particular advantage. Moreover, silicon is used widely in photonic applications because it is inexpensive, non-toxic, it has a large non-linear refractive index and is compatible with existing Si wafer technology.

Until now, the structure sizes in the sub-micrometer range have meant that most processes for producing two-dimensional photonic crystals have relied on lithography techniques, with the result that the maximum dimension of these materials is usually in the sub-millimeter range and production is very complex. Only a few sample sizes of not more than a few square centimeters have been produced, and the excessively large structure sizes have made it impossible to achieved the desired wavelength range in visible or near infrared (NIR) range with “telecommunication wavelengths”, that is to say 1.33 μm and 1.5 μm.

The materials with the largest area of a few square centimeters are produced according to the prior art by the use of electron beam lithography or nano-indentation and subsequent etching. However, in most cases the photonic bandgaps do not fall within the visible or near infrared wavelength range.

A two stage process for producing photonic crystals from air/TiO₂/nanorods is described in Adv. Mater. 2005, 17, 2103-2106. In this method, in a first step a continuous hexagonal pattern of gold nanoparticles is formed on a sapphire substrate. This gold pattern then functions as the catalyst in a wake-up process for the ZnO nanorods that are formed, said process being performed in an oven at elevated temperature. The height and diameter of the ZnO nanorods are determined by the thickness of the gold layer that is functioning as the catalyst and the wake-up time. In a second step, the ZnO nanorods are covered evenly with a layer of dielectric TiO₂, which is applied using a low-temperature ALD process. The TiO₂-coated ZnO nanorods form a photonic crystal with a bandgap at a wavelength of 2.3 μm according to simulation. Unfortunately, the period of these structures would have to be smaller by a factor of almost two for the calculated bandgap to fall within the wavelength range from 1.33 μm to 1.5 μm that is of interest for telecommunications, or in the visible range. In addition, the effective refractive index of ZnO structures coated with TiO₂ is only 2.2. Significantly larger bandgaps are possible with photonic crystals made from silicon or III-V semiconductors, such as GaAs, because of their much higher refractive index.

A method for producing a two-dimensional photonic band structure based on macroporous silicon is described in Appl. Phys. Lett. 68 (6), 5 February 1996. In this process, a regular arrangement of pores having a diameter in the micrometer range and a depth of a few hundred tm is first formed in silicon by means of an electrochemical process. Then, silicon columns with steep side walls are formed in this porous material by micro-machining. This technique can be used for producing photonic material having a bandgap in the IR range at a wavelength of 5 μm. However, the structure sizes would still have to be smaller by a factor of 3 to 4 before the bandgap would occur in the technologically interesting visible or NIR range.

A process in which a thin polycrystalline silicon film is deposited on a glass substrate coated with ZnO: Al by electron beam evaporation and subsequent thermal treatment is described in J. Appl. Phys. 106, 084506 (209). In this process, depending on the temperature regime, at deposition temperatures <400° C. grains in a size range from 1-3 nm and with random orientation were observed after electron beam evaporation and subsequent thermal crystallization, but with electron beam evaporation of Si at temperatures >400° C., columnar crystals reaching lengths of up 200 nm and with strong <110> orientation are formed immediately. These crystallites exhibit better solar cell parameters than the grains produced at temperatures <400° C.

Likewise in the 24th European Photovoltaic Solar Energy Conference, 21-25 September 2009, Hamburg, Germany, 2482-2485, silicon is deposited on various textured glasses by electron beam evaporation, and the morphology, growth and defect structure thereof is examined Another paper that appeared on pp. 2279-2285 of the proceedings of the same conference included a report on electron beam evaporation of thin silicon layers on textured glass substrates.

A solar cell concept based on crystalline thin silicon films on glass as a cheap substrate is described in Solar Energy 77 (2004) 857-863. The layers are produced by vapor phase deposition of amorphous silicon and subsequent solid phase crystallization by thermal heating at about 600° C. The concept combines the advantages of traditional silicon wafer technology, such as high material quality as well as the non-toxicity and good availability of crystalline silicon, with the benefits of thin-film technologies, which include the capability of series integrated circuitry for large area solar cells as well as low material consumption. It is also shown, in the proceedings of the 35th IEEE Photovoltaic Specialists Conference, 20-25 June 2010, Hawaii, USA, 614-619, that crystalline silicon layers which have been deposited by electron beam evaporation, a directional high volume deposition process, and subsequently crystallized in a thermal solid phase treatment result in comparable solar cell efficiencies.

Various methods for structuring substrates are also known from the prior art. For example, the 24th European Photovoltaic Solar Energy Conference, 21-25 September 2009,Hamburg, Germany, 2884-2886 contains a description of structuring of the front electrode in Si-based thin films by a sol-gel method. A report on this method is also included in DE 10 2005 036 427 A1, which deals with the production of a layer with partial- or full-surface macrostructuring on a substrate.

Microstructuring of flat glass substrates is described in DE 10 2004 049 233 A1, in which a substrate surface having at least one structured masking layer is coated and then undergoes a chemically reactive ion etching process with at least one chemical etching gas.

According to the prior art, there is no known method by which periodic crystalline silicon nanostructures having a periodicity less than 2 μm and large dimensions may be produced inexpensively.

### SUMMARY

An aspect of the invention provides a process for preparing a periodic crystalline silicon nanostructure, comprising: generating a periodic structure with a lattice constant a between 200 nm and 2 μm on a substrate, the substrate comprising a material that is stable up to at least 570° C., to obtain a periodically structured substrate comprising periodically alternating flat regions and steep flanks; then depositing silicon onto the periodically structured substrate in a directional deposition process with a substrate temperature of up to 400° C., to obtain a coated, structured substrate comprising a deposited Si layer having a thickness of from 0.2 to 3 times a Si lattice constant; and then thermally treating the deposited Si layer at a temperature between 570° C. and 1,400° C. for a period lasting from a few minutes to several days, to at least partially solid phase crystallize the deposited Si layer.

### BRIEF DESCRIPTION OF THE DRAWINGS

The present invention will be described in even greater detail below based on the exemplary figures. The invention is not limited to the exemplary embodiments. All features described and/or illustrated herein can be used alone or combined in different combinations in embodiments of the invention. The features and advantages of various embodiments of the present invention will become apparent by reading the following detailed description with reference to the attached drawings which illustrate the following:

FIG. 1: is an SEM image of a periodically structured glass substrate;

FIG. 2: is a TEM image of a silicon layer produced according to the inventive method after thermal crystallization;

FIG. 3: is an SEM image of a silicon layer produced according to the inventive method after removal of the porous regions by selective etching; FIGS. 4a-e: are SEM images of a silicon layer produced according to the inventive method after removal of the porous regions by selective etching for etching periods of various lengths;

FIG. 5: are angle-resolved reflection spectra with p-polarized light on the periodic nanostructures produced according to the invention; and

FIG. 6: is a photonic band structure of periodic nanostructures produced according to the invention in a 2D-simulation and determined experimentally from the angle-resolved reflection measurements of FIG. 5.

### DETAILED DESCRIPTION

In an embodiment the invention provides an inexpensive method for producing large-area periodic crystalline silicon nanostructures having a periodicity of less than 2 μm. In an aspect of the invention, 0.2 to 3 times the lattice constant of silicon may be from 40 nm to 6 μm.

The simple, inexpensive method enables the production of Si-based, two-dimensional photonic crystals over large areas. At the same time structure sizes as small as 200 nm are possible, so that the photonic bandgaps are within the desired visible and NIR wavelength range.

In one embodiment of the invention, a glass substrate is used as the substrate. However, any other substrate that can withstand temperatures above 570° C. and which has periodically recurring flat and steep regions may also be used. Regions are described and understood as being “flat” for the purposes of the present invention if the surface normal thereof forms an angle smaller than 20° with the surface normal of a planar substrate. Regions are described as “steep” if the surface normal thereof forms an angle greater than 35° with the surface normal of a planar substrate.

In one embodiment, the resulting porous silicon regions are removed by selective wet chemical etching of the Si layers in an optional process step. Since nanocrystalline porous silicon is etched much faster than the compact crystalline silicon regions by acids of any type, appropriate selection of the respective acids and suitable adjustment of the etching time result in freestanding silicon crystals. Etching processes of such kind from the prior art are known to a person with average skill in the art.

In a further embodiment, electron beam evaporation is used as the directed deposition process. Any kind of the thermal evaporation may be used to deposit Si on the flat and steep flanks of the substrate structure. Conformal deposition processes such as vapor phase epitaxy are less well suited. Due to the texture of the substrate, with directed deposition the silicon comes into contact with the surface at different angles. The silicon grows in an amorphous or semi-crystalline phase depending on the substrate temperature during deposition.

During the thermal treatment for the purpose of solid phase crystallization of silicon, two silicon phases are formed. In flat regions of the substrate, that is to say with almost perpendicular incidence of the silicon on the surface, crystalline silicon is formed. On steep flanks of the texture, however, porous nanocrystalline material grows.

In the following embodiment for producing two-dimensional periodic nanostructures, use is made of a glass substrate with a periodic structure that has a square lattice arrangement and lattice constants of 300 nm and 2 nm. These glasses were produced in a nanoimprint process, which has already been acknowledged as part of the prior art (see 24th European Photovoltaic Solar Energy Conference, 21-25 September 2009, Hamburg, Germany, pp. 2884). FIG. 1 shows an SEM image of such a periodically structured glass substrate. The structure with periodically recurring flat and steep regions/flanks is clearly visible.

Subsequently, a 1.4 μm thick layer of silicon is deposited on the structured glass substrate at a substrate temperature of 300° C.

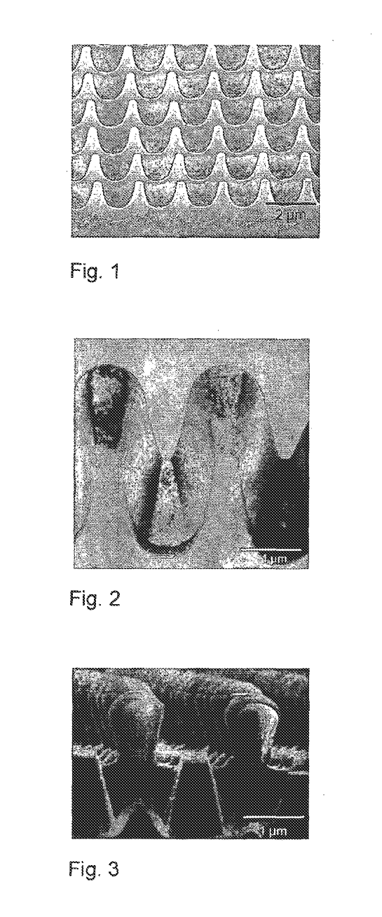

Then in the next process step, the applied Si layer, which was deposited in either an amorphous or semi-crystalline phase, undergoes complete solid-phase crystallization by heating at 600° C. for 20 hours. Two silicon phases are formed. In flat regions of the substrate, that is to say where the silicon is almost perpendicularly incident with the surface, a compact, crystalline silicon forms. On the other hand, on steep flanks of the texture porous nanocrystalline material grows. This is shown in FIG. 2 by the corresponding TEM micrograph.

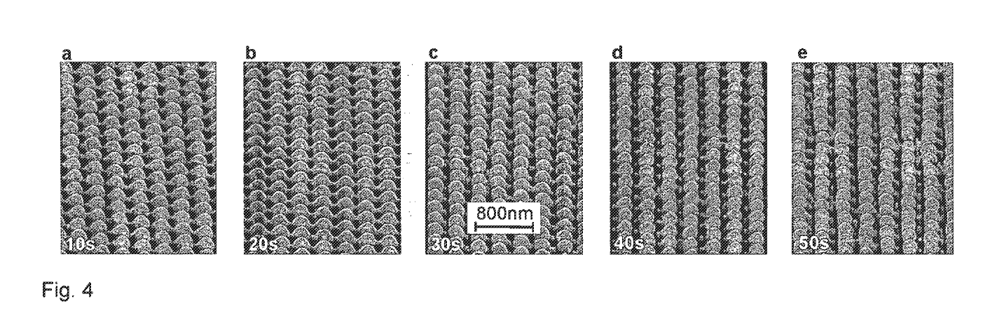

In this embodiment, the optional final step of selective wet-chemical etching is performed. In this context, the nanocrystalline porous silicon is removed from the steep flanks of the structures by a solution consisting of one part hydrofluoric acid in 50% concentration, 30 parts nitric acid in 65% concentration, 10 parts of phosphoric acid in 85% concentration and 15 parts water. Since the porous material is etched much faster than the compact crystalline silicon regions, with corresponding adjustment of the etching time, typically 40 to 90 seconds, freestanding silicon crystals emerge with layer thickness from 300 nm to 1.5 nm. An SEM micrograph of these silicon structures is shown in FIG. 3. The freestanding structures created by the method according to the invention have the following dimensions: height 1.4 nm, diameter from 0.3 nm to 0.8 nm. In this embodiment, the Si nanostructures were produced on an area of 10×10 cm². However, the inventive method is also scalable to cover larger areas.

By adjusting the etching time, it is possible to vary the diameter of the freestanding silicon structures. A series of SEM images of silicon structures that have been etched for various lengths of time is reproduced in FIGS. 4a-e (etching time specified in each picture). The periodicity in this case is 300 nm, the Si layer thickness is 235 nm.

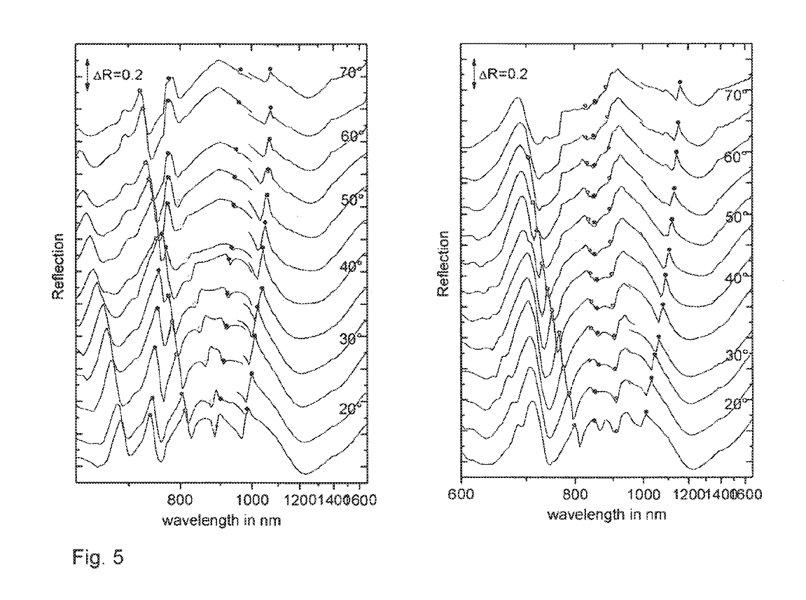

FIG. 5 shows angle-resolved reflection measurements along the two high symmetry directions on periodic silicon nanostructures produced according to the inventive method. The structures have a periodicity of 300 nm and a layer thickness of 270 nm. The optional etching step was not used with these structures. The incident light was p-polarized. According to Phys. Rev. B 60 (24), R16255, 1999, sharp resonances appear in the reflection spectra, and can be assigned to photonic bands of the structure. In FIG. 5, these resonances are marked by circles.

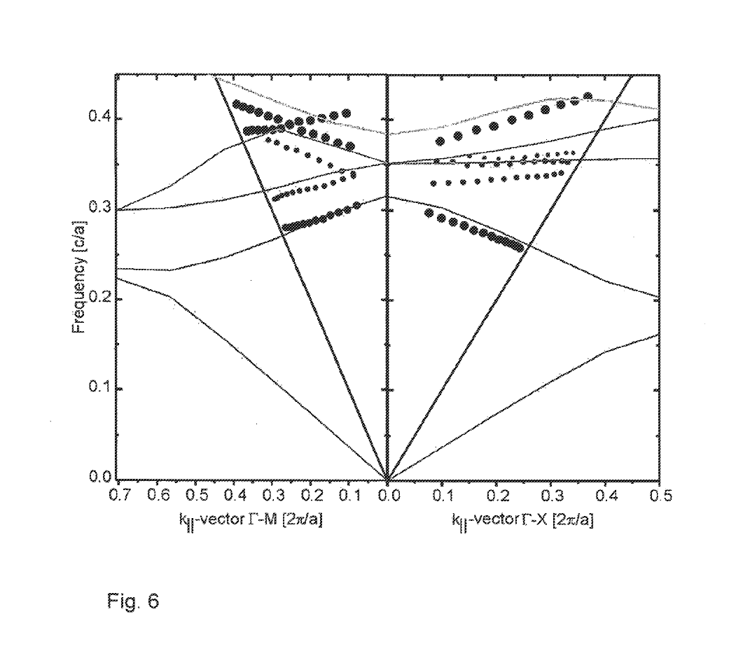

In FIGS. 5 and 6, the resonances determined experimentally are summarized as a photonic band structure (filled circles). The band structure of periodically arranged silicon columns calculated in 2D simulations is also indicated. This shows that the structures have a photonic stop band in the gamma-X direction at a frequency of approximately 0.19 c/a (where c is the speed of light in vacuum and a is the lattice constant), which corresponds a wavelength of 1.55 μm at a periodicity of a =300 nm, that is to say exactly a desired telecommunication wavelength.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B, and C” should be interpreted as one or more of a group of elements consisting of A, B, and C, and should not be interpreted as requiring at least one of each of the listed elements A, B, and C, regardless of whether A, B, and C are related as categories or otherwise. Moreover, the recitation of “A, B, and/or C” or “at least one of A, B, or C” should be interpreted as including any singular entity from the listed elements, e.g., A, any subset from the listed elements, e.g., A and B, or the entire list of elements A, B, and C.

1. A process for preparing a periodic crystalline silicon nanostructure, comprising:
generating a periodic structure with a lattice constant a between 200 nm and 2 μm on a substrate, the substrate comprising a material that is stable up to at least 570° C., to obtain a periodically structured substrate comprising periodically alternating flat regions and steep flanks; then
depositing silicon onto the periodically structured substrate in a directional deposition process with a substrate temperature of up to 400° C., to obtain a coated, structured substrate comprising a deposited Si layer having a thickness of from 0.2 to 3 times a Si lattice constant: and then
thermally treating the deposited Si layer at a temperature between 570° C. and 1,400° C. for a period lasting from a few minutes to several days, to at least partially solid phase crystallize the deposited Si layer.

2. The process of claim 1, further comprising, after the thermally treating the deposited Si layer;
selectively etching the deposited Si layer in a wet chemical process to remove the porous Si regions formed.

3. The process of claim 1, wherein the substrate comprises glass.

4. The process of claim 1, wherein electron beam evaporation is used as a directed deposition method.

5. The process of claim 2, wherein the selectively etching enhances solid phase crystallization.

6. The process of claim 1, wherein the depositing deposits amorphous silicon.

7. The process of claim 1, wherein the depositing deposits semi-crystalline silicon.

8. The process of claim 1, wherein the depositing deposits amorphous silicon and semi-crystalline silicon.

9. The process of claim 1, wherein a periodicity of the periodically alternating flat regions and steep flanks less than 2 μm.

10. The process of claim 1, wherein the depositing deposits a silicon layer with a thickness of from 40 nm to 6 μm.

11. The process of claim 1, wherein the thermally treating forms two silicon phases.

12. The process of claim 1, wherein the thermally treating forms crystalline silicon in at least one of the fiat regions of the substrate.

13. The process of claim 1, wherein the thermally treating forms porous nanocrystallinc material on at least one of the steep flanks of the texture.

14. The process of claim 1, wherein the substrate temperature of the depositing is in a range of from 300° C. to 400° C.

15. The process of claim 1, wherein the period of the thermally treating lasts from a few minutes to 20 hours.

16. The process of claim 1, wherein the thermally treating is carried out at a temperature between 570° C. and 600° C.

17. The process of claim 1, wherein the thermally treating is carried out at a temperature between 600° C. and 1,400° C.

18. The process of claim 2, wherein the substrate comprises glass.

19. The process of claim 2, wherein the etching is carried out for between 40 to 90 seconds.
